(19) United States
(12) Patent Application Publication
(10) Pub. No.: US 2022/0230873 A1
(43) Pub. Date: Jul. 21, 2022

(54) CLEANING METHOD AND CLEANING DEVICE FOR WAFER EDGE

(71) Applicant: CHANGXIN MEMORY TECHNOLOGIES, INC., Hefei City (CN)

(72) Inventors: Xiaobo MEI, Hefei City (CN); Haodong LIU, Hefei City (CN)

(73) Assignee: CHANGXIN MEMORY TECHNOLOGIES, INC., Hefei City (CN)

(21) Appl. No.: 17/456,669

(22) Filed: Nov. 29, 2021

Related U.S. Application Data
(63) Continuation of application No. PCT/CN2021/107895, filed on Jul. 22, 2021.

(30) Foreign Application Priority Data
Jan. 21, 2021 (CN) 202110083429.1

(51) Int. Cl. H01L 21/02; H01L 21/687; H01L 21/67

(52) U.S. Cl. CPC H01L 21/02087; H01L 21/02057; H01L 21/67051; H01L 21/68764

(57) ABSTRACT

A cleaning method includes: providing a wafer, the wafer having a wafer edge; and controlling the wafer in a rotation phase to rotate the wafer, and providing a cleaning solution for the wafer edge in the rotation phase. The rotation phase includes a first rotation phase and/or a second rotation phase. A rotation speed of the wafer increases from a first speed to a second speed during the first rotation phase, and the rotation speed of the wafer decreases from the second speed to the first speed during the second rotation phase. The second speed is greater than the first speed.

### CROSS-REFERENCE TO RELATED APPLICATIONS

This is a continuation of International Patent Application No. PCT/CN2021/107895 filed on Jul. 22, 2021, which claims priority to Chinese Patent Application No. 202110083429.1 filed on Jan. 21, 2021. The disclosures of the above-referenced applications are hereby incorporated by reference in their entirety.

### BACKGROUND

In a semiconductor manufacturing process, a wafer edge is generally required to be cleaned to remove a film layer on the wafer edge, so as to ensure a normal subsequent process.

### SUMMARY

Embodiments of the present disclosure relate to the field of semiconductors, and in particular, to a cleaning method and cleaning device for a wafer edge.

The embodiments of the present disclosure provide a cleaning method and cleaning device for a wafer edge, which help solve the problem of a poor cleaning effect of the wafer edge.

The embodiments of the present disclosure provide a cleaning method for a wafer edge, including: providing a wafer, the wafer having a wafer edge; and controlling the wafer in a rotation phase to rotate the wafer, and providing a cleaning solution for the wafer edge in the rotation phase; the rotation phase including a first rotation phase and/or a second rotation phase, a rotation speed of the wafer increasing from a first speed to a second speed during the first rotation phase, and the rotation speed of the wafer decreasing from the second speed to the first speed during the second rotation phase; and the second speed being greater than the first speed.

The embodiments of the present disclosure further provide a cleaning device for a wafer edge, including: a wafer and a stage configured to place the wafer; a control device, the control device being configured to control a rotation speed of the wafer, the rotation speed of the wafer increasing from a first speed to a second speed or decreasing from the second speed to the first speed, the second speed being greater than the first speed; and a spraying device, the spraying device being configured to provide a cleaning solution for the rotating wafer edge.

### BRIEF DESCRIPTION OF THE DRAWINGS

One or more embodiments are exemplarily described by using figures that are corresponding thereto in the accompanying drawings; the exemplary descriptions do not constitute limitations on the embodiments. Elements with same reference numerals in the accompanying drawings are similar elements. Unless otherwise particularly stated, the figures in the accompanying drawings do not constitute a scale limitation.

FIG. 1 is a line chart of time versus speed of wafer cleaning in a cleaning method for a wafer edge;

FIG. 2 is a first schematic structural diagram of steps of the cleaning method for the wafer edge according to a first embodiment of the present disclosure;

FIG. 3 is a second schematic structural diagram of steps of the cleaning method for the wafer edge according to the first embodiment of the present disclosure;

FIG. 4 is a third schematic structural diagram of steps of the cleaning method for the wafer edge according to the first embodiment of the present disclosure;

FIG. 5 is a line chart of time versus speed of wafer cleaning performed with a cleaning solution in the cleaning method for the wafer edge according to the first embodiment of the present disclosure;

FIG. 6 is another line chart of time versus speed of wafer cleaning performed with a cleaning solution in the cleaning method for the wafer edge according to the first embodiment of the present disclosure;

FIG. 7 is yet another line chart of time versus speed of wafer cleaning performed with the cleaning solution in the cleaning method for the wafer edge according to the first embodiment of the present disclosure;

FIG. 8 is a bar chart of a cleaning effect of the cleaning method for the wafer edge according to the first embodiment of the present disclosure;

FIG. 9 is a line chart of time versus speed of wafer cleaning performed with the cleaning solution in a cleaning method for the wafer edge according to a second embodiment of the present disclosure;

FIG. 10 is another line chart of time versus speed of wafer cleaning performed with the cleaning solution in the cleaning method for the wafer edge according to the second embodiment of the present disclosure; and

FIG. 11 is a schematic structural diagram of a cleaning device for the wafer edge according to a third embodiment of the present disclosure.

### DETAILED DESCRIPTION

A method for cleaning a wafer edge typically involves: providing a cleaning solution for the wafer edge, which leads to incomplete cleaning of a surface film layer of the wafer edge; or rotating a wafer when the wafer edge is cleaned, which leads to a non-ideal cleaning effect, makes it difficult to clean the wafer completely, and easily forms residue after cleaning, resulting defects in semiconductor products.

Some embodiments of the present application can provide a cleaning method for a wafer edge to reduce or eliminate the defects caused by the cleaning of the wafer edge.

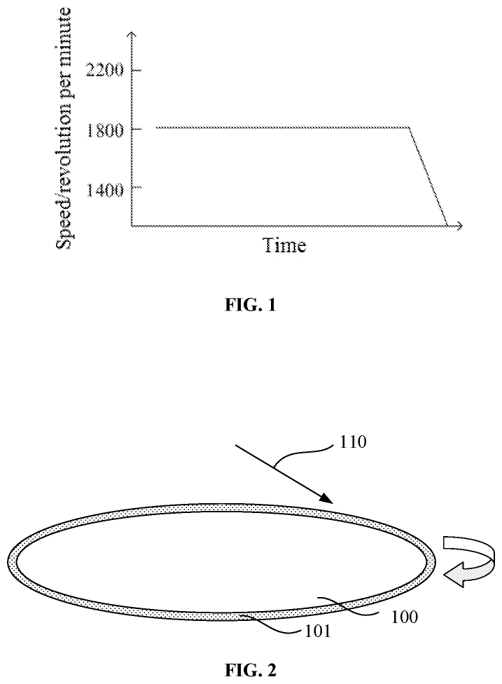

FIG. 1 is a line chart of time versus speed of wafer cleaning in a cleaning method for a wafer edge.

Referring to FIG. 1, in a cleaning method for a wafer edge, when the wafer edge is cleaned, a wafer rotates to provide a centripetal force for a cleaning solution on the wafer, so that the cleaning solution stays as close to the wafer edge as possible. The wafer rotates at a constant speed, which is normally set to 1800 revolutions per minute. According to analysis, if the speed of the wafer is stable, the wafer provides the cleaning solution with only a support force and a force parallel to a surface of the wafer, but cannot provide a force toward the surface of the wafer. As a result, an adhesion force between the wafer edge and the cleaning solution is insufficient, and a transition layer at the wafer edge reacts poorly with the cleaning solution. The transition layer is difficult to be completely cleaned, and residue is easy to form after cleaning, resulting in defects in semiconductor products.

In order to solve the above problem, an embodiment of the present disclosure provides a cleaning method for a wafer edge. A rotation phase of a wafer includes a first rotation phase and/or a second rotation phase, a rotation speed of the wafer increases from a first speed to a second speed during the first rotation phase, the rotation speed of the wafer decreases from the second speed to the first speed during the second rotation phase, and the second speed is greater than the first speed. The rotation speed of the wafer changes, and the cleaning solution produces turbulence on a surface of the wafer. The turbulence increases an adhesion force between the cleaning solution and the wafer edge, and the cleaning solution reacts more thoroughly with the wafer edge, which facilitates more thorough cleaning of the wafer edge. After the cleaning, the residue is reduced and the cleaning effect of the wafer edge is improved.

In order to make the objectives, technical solutions and advantages of the embodiments of the present disclosure clearer, various embodiments of the present disclosure will be described below in detail with reference to the drawings. However, those of ordinary skill in the art may understand that, in the embodiments of the present disclosure, numerous technical details are set forth in order to enable a reader to better understand the present disclosure. However, the technical solutions claimed in the present disclosure can be implemented without these technical details and various changes and modifications based on the embodiments below.

FIG. 2 to FIG. 4 are schematic structural diagrams of steps of a cleaning method for a wafer edge according to a first embodiment of the present disclosure.

Referring to FIG. 2, a wafer 100 is provided.

The wafer 100 has a wafer edge 101. The wafer edge 101 has an inclined region, i.e., an edge region. A thickness of the edge region gradually decreases in a direction away from a central axis of the wafer 100.

It may be understood that subsequent cleaning of the wafer edge 101 mainly involves cleaning the edge region.

In one example, the wafer 100 may include a substrate and a film layer located on the substrate. The film layer located in the edge region may be made of titanium nitride, oxide or polysilicon. It is to be noted that this embodiment does not limit the film layer of the edge region, and the film layer may be made of a different material according to a different semiconductor manufacturing process performed on a surface of the substrate. In this embodiment, the film layer is made of, for example, titanium nitride.

A cleaning solution may be subsequently provided for the wafer edge 101 for cleaning. Prior to the step of providing a cleaning solution for the wafer edge 101, the method may further include: performing pretreatment 110. The pretreatment 110 involves providing deionized water for the wafer edge 101 to soften the wafer edge 101.

Specifically, the purpose of pretreatment 110 is as follows: a surface of the wafer edge 101 is brittle in general, and the film layer on the surface of the wafer edge 101 is prone to brittle fracture and splash during subsequent cleaning; since the wafer edge 101 is hydrophilic, deionized water may be provided for the wafer edge 101 to soften the wafer edge 101 through the pretreatment 110 to reduce the brittleness of the surface of the wafer edge 101, so as to help prevent brittle fracture and splash of the wafer edge 101 during the subsequent cleaning and further improve the cleaning effect of the wafer edge 101.

For example, the film layer on the surface of the wafer edge 101 is made of titanium nitride which is brittle and is prone to brittle fracture or splash during the subsequent cleaning. Brittle or splashy substances are difficult to remove, which results in residue after the cleaning. In addition, a complex morphology of the edge region also makes it easy for the brittle or splashy substances to remain. Titanium nitride is hydrophilic, and the contact between deionized water and titanium nitride may reduce the brittleness of titanium nitride, thereby reducing the probability of brittle fracture or splash during the subsequent cleaning.

In this embodiment, during the pretreatment 110, the wafer 100 is rotated. The rotated wafer 100 enables the deionized water to more fully contact with the wafer edge 101, which can soften the entire wafer edge 101 and achieve a better softening effect.

In one example, during the pretreatment 110, a rotation speed of the wafer 100 may range from 1600 revolutions per minute to 2000 revolutions per minute, which may specifically be 1700 revolutions per minute, 1800 revolutions per minute or 1900 revolutions per minute.

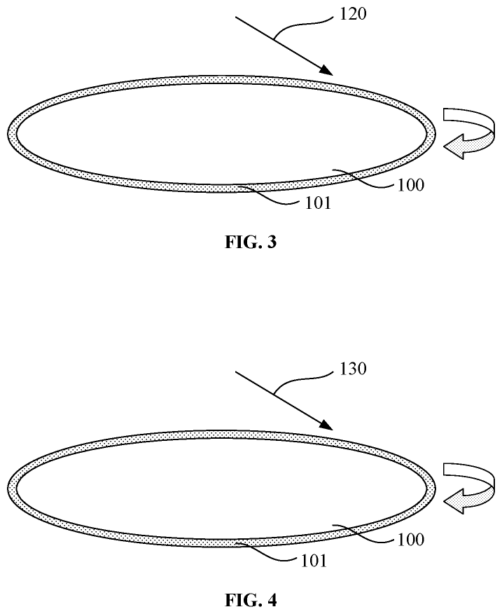

Referring to FIG. 3, the wafer 100 is controlled in a rotation phase to rotate the wafer 100, and a cleaning solution 120 is provided for the wafer edge 101 in the rotation phase.

In this embodiment, a to-be-cleaned film layer of the wafer edge 101 is made of titanium nitride, and the cleaning solution 120 is a mixture of ammonia, water and hydrogen peroxide; that is, the cleaning solution is a SCl solution.

In other embodiments, the cleaning solution may also be a hydrofluoric acid solution or a nitrofluoric acid solution. It may be understood that how to select a type of the cleaning solution is related to a material of a to-be-removed film layer on the surface of the wafer edge. For example, when the to-be-removed film layer on the surface of the wafer edge is made of an oxide, the cleaning solution is a hydrofluoric acid solution; when the to-be-removed film layer on the surface of the wafer edge is made of polysilicon, the cleaning solution is a nitrofluoric acid solution.

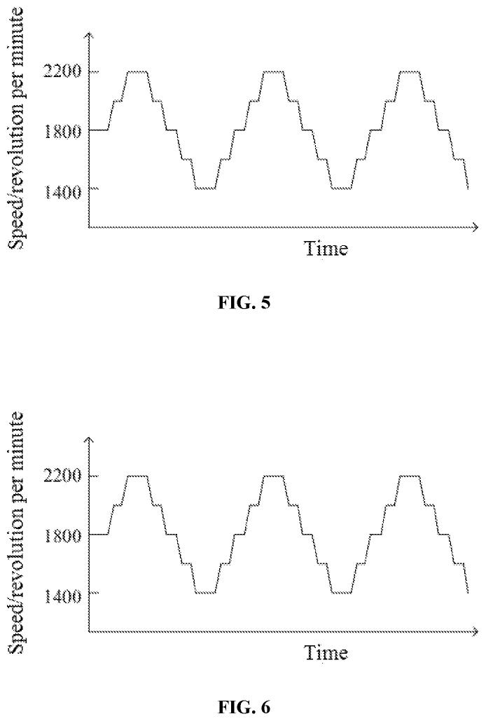

FIG. 5 is a line chart of time versus speed of wafer cleaning performed with a cleaning solution in the cleaning method for a wafer edge according to this embodiment.

Referring to FIG. 5, a rotation phase includes a first rotation phase and a second rotation phase, a rotation speed of the wafer 100 increases from a first speed to a second speed during the first rotation phase, the rotation speed of the wafer 100 decreases from the second speed to the first speed during the second rotation phase, and the second speed is greater than the first speed.

It may be obtained that, during the cleaning, the rotation speed of the wafer 100 changes between the first speed and the second speed, and a change in the rotation speed of the wafer 100 causes the cleaning solution 120 to produce turbulence on the surface of the wafer 100. The turbulence increases an adhesion force between the cleaning solution 120 and the wafer edge 101, and the cleaning solution 120 reacts more thoroughly with the wafer edge 101, which facilitates more thorough cleaning of the wafer edge 101. After the cleaning, the residue is reduced and the cleaning effect of the wafer edge 101 is improved.

In this embodiment, the rotation phase including a first rotation phase and a second rotation phase is specifically: the rotation phase including the first rotation phase and the second rotation phase alternately performed.

During the cleaning, the rotation speed of the wafer 100 alternately changes between the first speed and the second speed, and an alternate change in the rotation speed of the wafer 100 causes the cleaning solution 120 to produce turbulence on the surface of the wafer 100. The turbulence increases an adhesion force between the cleaning solution 120 and the wafer edge 101, and the cleaning solution 120 reacts more thoroughly with the wafer edge 101, which facilitates more thorough cleaning of the wafer edge 101. After the cleaning, the residue is reduced and the cleaning effect of the wafer edge 101 is improved.

In other embodiments, the rotation phase of the wafer 100 includes only one first rotation phase and one second rotation phase.

In this embodiment, the first rotation phase includes: an acceleration phase and a first stabilization phase; and the second rotation phase includes: a deceleration phase and a second stabilization phase.

The wafer 100 is kept constant at the second speed in the first stabilization phase, and the wafer 100 is kept constant at the first speed in the second stabilization phase. The first stabilization phase and the second stabilization phase are added subsequent to the acceleration phase and the deceleration phase, which helps stabilize the wafer 100. Since the rotation speed of the wafer 100 cannot switch seamlessly from rise to fall or from fall to rise, a transition phase from rise to plateau and then fall or from fall to plateau and then rise is required. With the addition of the first stabilization phase and the second stabilization phase, a change trend of the rotation speed of the wafer 100 may not make the wafer 100 unstable due to a sudden change, thereby improving the stability of the cleaning of the wafer edge 101.

In other embodiments, the first rotation phase may include only an acceleration phase, and the second rotation phase may include only a deceleration phase.

A duration of the first stabilization phase and a duration of the second stabilization phase range from 0.2 seconds to 0.5 seconds, which may specifically be 0.3 seconds or 0.4 seconds. The duration of the first stabilization phase and the duration of the second stabilization phase are shorter, which not only ensures the stability of the cleaning of the wafer edge 101, but also reduces a duration of the cleaning of the wafer edge 101, thereby improving the cleaning efficiency.

In this embodiment, the first rotation phase and the second rotation phase alternately performed included in the rotation phase are specifically an acceleration phase, a first stabilization phase, a deceleration phase and a second stabilization phase alternately performed. With the addition of the first stabilization phase and the second stabilization phase during the alternate change in the speed of the wafer 100, a change trend of the rotation speed of the wafer 100 may not make the wafer 100 unstable due to a sudden change, thereby improving the stability of the cleaning of the wafer edge 101.

In other embodiments, the rotation phase may also include an acceleration phase, a first stabilization phase and a deceleration phase alternately performed.

The second speed is greater than the first speed. The second speed is greater than the first speed, the speed of the wafer 100 changes between the two different speeds, a changing speed of the wafer 100 causes the cleaning solution 120 to form turbulence on the surface of the wafer 100, and the turbulence increases adhesion between the wafer edge 101 and the cleaning solution 120, thereby improving the cleaning effect.

Specifically, the first speed ranges from 1200 revolutions per minute to 1600 revolutions per minute, which may specifically be 1300 revolutions per minute, 1400 revolutions per minute or 1500 revolutions per minute; the second speed ranges from 2000 revolutions per minute to 2400 revolutions per minute, which may specifically be 2100 revolutions per minute, 2200 revolutions per minute or 2300 revolutions per minute.

In this embodiment, the rotation speed of the wafer 100 increases linearly from the first speed to the second speed during the first rotation phase; and the rotation speed of the wafer 100 decreases linearly from the second speed to the first speed during the second rotation phase.

The speed of the wafer 100 alternates between the first speed and the second speed by linear increase and linear decrease, and the speed of the wafer 100 changes steadily, which prevents the influence on the cleaning effect and the pollution of a reaction chamber caused by the splashing of the cleaning solution 120 on the surface of wafer edge 101 due to an over-large acceleration change in the speed.

A speed of the linear increase ranges from 200 revolutions per minute per second to 1200 revolutions per minute per second, which may specifically be 400 revolutions per minute, 800 revolutions per minute or 1000 revolutions per minute; and a speed of the linear decrease ranges from 200 revolutions per minute per second to 1200 revolutions per minute per second, which may specifically be 400 revolutions per minute, 800 revolutions per minute or 1000 revolutions per minute.

It may be obtained that a maximum speed difference between the first speed and the second speed is 1200 revolutions per minute, and a minimum linear increase or decrease speed is 200 revolutions per minute per second, from which a maximum duration of the acceleration phase is calculated to be 6 seconds. A minimum speed difference between the first speed and the second speed is 400 revolutions per minute, and a maximum linear increase or decrease speed is 1200 revolutions per minute per second, from which a minimum duration of the acceleration phase is calculated to be 0.34 seconds. Therefore, a time during which the rotation speed of the wafer 100 increases from the first speed to the second speed or decreases from the second speed to the first speed ranges from 0.34 seconds to 6 seconds, which may be 1 second, 3 seconds or 5 seconds specifically.

FIG. 6 is another line chart of time versus speed of wafer cleaning performed with the cleaning solution in the cleaning method for a wafer edge according to this embodiment.

Referring to FIG. 6, in other embodiments, the rotation speed of the wafer 100 increases arithmetically from the first speed to the second speed during the first rotation phase; and the rotation speed of the wafer 100 decreases arithmetically from the second speed to the first speed during the second rotation phase.

The speed of the wafer 100 alternates between the first speed and the second speed by arithmetic increase and arithmetic decrease. Each time the speed of the wafer 100 changes according to a preset tolerance, the speed may remain stable for a period of time before the next change. A stable duration at the first speed or the second speed is greater than a stable duration when the wafer 100 is at other speeds. The speed of the wafer 100 changes steadily between each arithmetic increase or arithmetic decrease.

A tolerance of the arithmetic increase ranges from 200 revolutions per minute to 1200 revolutions per minute, which may specifically be 400 revolutions per minute, 800 revolutions per minute or 1000 revolutions per minute; and a tolerance of the arithmetic decrease ranges from 200 revolutions per minute to 1200 revolutions per minute, which may specifically be 400 revolutions per minute, 800 revolutions per minute or 1000 revolutions per minute.

A time interval between each two changes in the speed of the wafer 100 ranges from 0.1 seconds to 1 second, which may specifically be 0.3 seconds, 0.6 seconds or 0.9 seconds. The time interval between each two changes in the speed of the wafer 100 is controlled to be shorter, which helps rapidly change the rotation speed of the wafer 100, can quickly form turbulence, and improves the cleaning effect of the wafer edge 101.

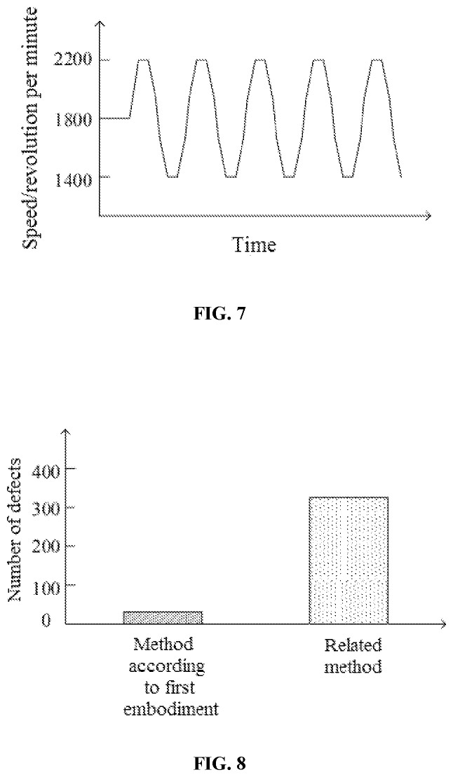

FIG. 7 is yet another line chart of time versus speed of wafer cleaning performed with the cleaning solution in the cleaning method for a wafer edge according to this embodiment.

In other embodiments, referring to FIG. 7, during the first rotation phase, the rotation speed of the wafer 100 increases from the first speed to the second speed specifically in three phases; in a first phase, acceleration of the speed of the wafer 100 gradually becomes greater, and the speed of the wafer 100 increases faster; in a second phase, the acceleration of the speed of the wafer 100 remains unchanged, and the speed of the wafer 100 increases steadily; in a third phase, the acceleration of the speed of the wafer 100 gradually becomes smaller, and the speed of the wafer 100 increases more slowly. During the second rotation phase, the rotation speed of the wafer 100 decreases from the second speed to the first speed specifically in three phases; in a first phase, deceleration of the speed of the wafer 100 gradually becomes greater, and the speed of the wafer 100 decreases faster; in a second phase, the deceleration of the speed of the wafer 100 remains unchanged, and the speed of the wafer 100 decreases steadily; in a third phase, the deceleration of the speed of the wafer 100 gradually becomes smaller, and the speed of the wafer 100 decreases more slowly. It may be obtained that, when the speed of the wafer 100 is close to the first speed and the second speed, the acceleration of the speed change is relatively small, which helps maintain the stability of the wafer 100 during the acceleration.

Still referring to FIG. 5, in this embodiment, each first rotation phase and each second rotation phase constitute a cleaning cycle, and the rotation phase includes a number of cleaning cycles with a same time. The time of each cleaning cycle is controlled to be the same. One cleaning cycle is an accurate quantization unit, which helps accurately quantify cleaning durations required by different wafer edges 101, without resetting parameters of the cleaning cycle for each wafer 100, thereby improving the cleaning efficiency of the wafer edge 101. In other embodiments, the time of each cleaning cycle may vary.

In this embodiment, the time of the first rotation phase of each cleaning cycle is the same, from which it can be obtained that the second rotation phase of each cleaning cycle is also the same and the time of the first rotation phase and the time of the second rotation phase are also the same. In this way, upon comparison, the acceleration in the first rotation phase and the deceleration in the second rotation phase have the same value and opposite directions, and there is no need to reset rotation data in each first rotation phase and each second rotation phase, which simplifies the operation and improves the cleaning efficiency of the wafer edge 101. In other embodiments, the time of the first rotation phase and the time of the second rotation phase may also be different.

In this embodiment, a duration of one cleaning cycle ranges from 1.2 seconds to 13 seconds, which may specifically be 4 seconds, 8 seconds or 12 seconds. It can be obtained from the above that the time of the first rotation phase and the time of the second rotation phase range from 0.34 seconds to 6 seconds, the duration of the first rotation phase and the duration of the second rotation phase range from 0.2 seconds to 0.5 seconds, and one cleaning cycle includes one first rotation phase, one second rotation phase, one first stabilization phase and one second stabilization phase, from which it can be calculated that the longest time of a complete cleaning cycle is 13 seconds and the shortest is 1.2 seconds.

It takes at least 5 cleaning cycles to clean the wafer edge 101 by using the method for cleaning the wafer edge 101 according to this embodiment. After 5 cleaning cycles, the wafer edge 101 is cleaned.

Referring to FIG. 4, after the cleaning solution 120 (refer to FIG. 3) is provided for the wafer edge 101, after-treatment 130 is performed on the wafer 100. The after-treatment 130 involves providing deionized water for the wafer 100 to remove by-products of the reaction between the cleaning solution 120 and the wafer edge 101, so as to prevent the influence of the by-products on a subsequent process of the wafer 100 and improve the cleaning effect of the method for cleaning the wafer edge 101.

After the after-treatment 130, the wafer 100 is dried and rotated to remove the deionized water remaining on the wafer 100, so that the wafer 100 can be dried quickly. The dried wafer 100 has better stability in the subsequent manufacturing process.

FIG. 8 is a bar chart of a cleaning effect of the cleaning method for a wafer edge according to this embodiment.

Referring to FIG. 8, it can be obtained that after the wafer 100 (refer to FIG. 4) is cleaned by using the cleaning method for the wafer edge 101 (refer to FIG. 4) according to this embodiment, a number of defects on the wafer 100 is less than 100; after the wafer 100 is cleaned by using a related method, the number of defects on the wafer 100 is greater than 300; so the method according to this embodiment has a better effect.

In the cleaning method for the wafer edge 101 according to this embodiment, a cleaning solution is provided for the wafer edge 101 in a rotation phase of a wafer 100, wherein the rotation phase includes a first rotation phase and a second rotation phase, a rotation speed of the wafer 100 increases from a first speed to a second speed during the first rotation phase, the rotation speed of the wafer 100 decreases from the second speed to the first speed during the second rotation phase, and the second speed is greater than the first speed. It may be obtained that, during the cleaning, the rotation speed of the wafer 100 changes between the first speed and the second speed, and a change in the rotation speed of the wafer 100 causes the cleaning solution to produce turbulence on a surface of the wafer 100. The turbulence increases an adhesion force between the cleaning solution and the wafer edge 101, and the cleaning solution reacts more thoroughly with the wafer edge 101, which facilitates more thorough cleaning of the wafer edge 101. After the cleaning, the residue is reduced and the cleaning effect of the wafer edge 101 is improved.

A second embodiment of the present disclosure provides a cleaning method for a wafer edge, which is substantially the same as the first embodiment of the present disclosure. Their main difference lies in that the rotation phase according to this embodiment includes only a first rotation phase or a second rotation phase. The cleaning method for a wafer edge according to the second embodiment of the present disclosure is described in detail below with reference to the accompanying drawings. The contents identical to or corresponding to those in the foregoing embodiment may be obtained with reference to the detail description in the foregoing embodiment, which is not described in detail below.

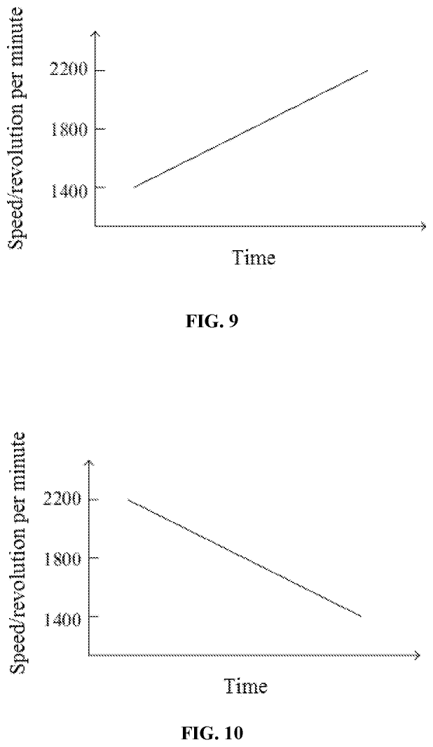

FIG. 9 is a line chart of time versus speed of wafer cleaning performed with a cleaning solution in a cleaning method for a wafer edge according to a second embodiment of the present disclosure. FIG. 10 is another line chart of time versus speed of wafer cleaning performed with the cleaning solution in the cleaning method for a wafer edge according to the second embodiment of the present disclosure.

In this embodiment, the rotation phase of the wafer 100 (refer to FIG. 3) includes only a first rotation phase or a second rotation phase.

Referring to FIG. 9, the rotation phase of the wafer 100 includes only a first rotation phase. A rotation speed of the wafer 100 increases from a first speed to a second speed during the first rotation phase. The second speed is greater than the first speed.

The rotation speed of the wafer 100 increases from the first speed to the second speed, so that the cleaning solution on the surface of the wafer 100 produces turbulence. The turbulence increases an adhesion force between the cleaning solution and the wafer edge 101 (refer to FIG. 3), and the cleaning solution reacts more thoroughly with the wafer edge 101, which facilitates more thorough cleaning of the wafer edge 101. After the cleaning, residue is reduced and the cleaning effect of the wafer edge 101 is improved.

Referring to FIG. 10, the rotation phase of the wafer 100 includes only a second rotation phase. The rotation speed of the wafer 100 decreases from the second speed to the first speed during the second rotation phase. The second speed is greater than the first speed.

The rotation speed of the wafer 100 decreases from the second speed to the first speed, so that the cleaning solution on the surface of the wafer 100 produces turbulence. The turbulence increases an adhesion force between the cleaning solution and the wafer edge 101, and the cleaning solution reacts more thoroughly with the wafer edge 101, which facilitates more thorough cleaning of the wafer edge 101. After the cleaning, the residue is reduced and the cleaning effect of the wafer edge 101 is improved.

A third embodiment of the present disclosure provides a cleaning device for a wafer edge corresponding to the cleaning method for a wafer edge according to the first embodiment, which is described in detail below with reference to the accompanying drawings.

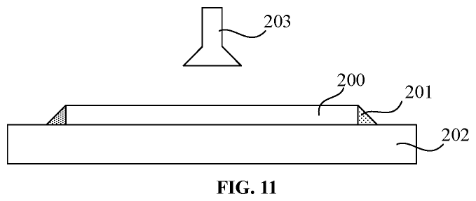

FIG. 11 is a schematic structural diagram of a cleaning device for a wafer edge according to a third embodiment of the present disclosure.

Referring to FIG. 11, the cleaning device for a wafer edge includes: a wafer 200 and a stage 202 configured to place the wafer 200; a control device (not marked), the control device being configured to control a rotation speed of the wafer 200, the rotation speed of the wafer 200 increasing from a first speed to a second speed or decreasing from the second speed to the first speed, the second speed being greater than the first speed; and a spraying device 203, the spraying device 203 being configured to provide a cleaning solution for the rotating wafer edge 201.

The wafer 200 has a wafer edge 201. An upper surface at the wafer edge 201 is an inclined surface inclined toward a lower surface of the wafer 200, i.e., an edge region. A thickness of the edge region gradually decreases in a direction away from a central axis of the wafer 200.

In one example, the wafer 200 may include a substrate and a film layer located on the substrate. The film layer located in the edge region may be made of titanium nitride, oxide or polysilicon. It is to be noted that this embodiment does not limit the film layer of the edge region, and the film layer may be made of a different material according to a different semiconductor manufacturing process performed on a surface of the substrate. In this embodiment, the film layer is made of, for example, titanium nitride.

A water supply device is further included. The water supply device is configured to provide deionized water for the wafer 200.

Generally, a surface of the wafer edge 201 is brittle, and the film layer on the surface of the wafer edge 201 is prone to brittle fracture and splash during subsequent cleaning; since the wafer edge 201 is hydrophilic, deionized water may be provided by the water supply device for the wafer edge 200 to soften the wafer edge 201 to reduce the brittleness of the surface of the wafer edge 201, so as to help prevent brittle fracture and splash of the wafer edge 201 during the cleaning and further improve the cleaning effect of the wafer edge 201.

For example, the film layer on the surface of the wafer edge 201 is made of titanium nitride which is brittle and is prone to brittle fracture or splash during the subsequent cleaning. Brittle or splashy substances are difficult to remove, which results in residue after the cleaning. In addition, a complex morphology of the edge region also makes it easy for the brittle or splashy substances to remain. Titanium nitride is hydrophilic, and the contact between deionized water and titanium nitride may reduce the brittleness of titanium nitride, thereby reducing the probability of brittle fracture or splash during the subsequent cleaning.

The control device includes a timing device configured to record a duration for cleaning the wafer edge 201. A duration of each cleaning of the wafer edge 201 is recorded, which helps statistically analyze the cleaning time of the wafer edge 201 made of different coating materials and having different thicknesses.

The control device is further configured to control a time during which the rotation speed of the wafer 200 increases from the first speed to the second speed to be the same as a time during which the rotation speed of the wafer 200 decreases from the second speed to the first speed.

In this way, upon comparison, the acceleration in the first rotation phase and the deceleration in the second rotation phase have the same value and opposite directions, and there is no need to reset rotation data in each first rotation phase and each second rotation phase, which simplifies the operation and improves the cleaning efficiency of the wafer edge 201.

In the cleaning device for the wafer edge 201 according to this embodiment, during the cleaning, the rotation speed of the wafer 200 changes between the first speed and the second speed, and the change in the rotation speed of the wafer 200 causes the cleaning solution to produce turbulence on the surface of the wafer 200. The turbulence increases an adhesion force between the cleaning solution and the wafer edge 201, and the cleaning solution reacts more thoroughly with the wafer edge 201, which facilitates more thorough cleaning of the wafer edge 201. After the cleaning, the residue is reduced and the cleaning effect of the wafer edge 201 is improved.

Various embodiments of the present disclosure can have one or more of the following advantages.

In the cleaning method for a wafer edge according to the embodiments of the present application, a cleaning solution is provided for a wafer edge in a rotation phase of a wafer, wherein the rotation phase includes a first rotation phase and/or a second rotation phase, a rotation speed of the wafer increases from a first speed to a second speed during the first rotation phase, the rotation speed of the wafer decreases from the second speed to the first speed during the second rotation phase, and the second speed is greater than the first speed. It may be obtained that, during the cleaning, the rotation speed of the wafer changes between the first speed and the second speed, and a change in the rotation speed of the wafer causes the cleaning solution to produce turbulence on a surface of the wafer. The turbulence increases an adhesion force between the cleaning solution and the wafer edge, and the cleaning solution reacts more thoroughly with the wafer edge, which facilitates more thorough cleaning of the wafer edge. After the cleaning, residue is reduced and the cleaning effect of the wafer edge is improved.

In addition, prior to the step of providing a cleaning solution for the wafer edge, the method according to the embodiments of the present application further includes: performing pretreatment, i.e., providing deionized water for the wafer edge to soften the wafer edge. Due to the brittleness, the wafer is prone to brittle fracture and splash during the cleaning, resulting in a defect of being difficult to remove. At the same time, the wafer edge is also hydrophilic, and deionized water may be provided for the wafer edge to soften the wafer edge prior to cleaning, which helps prevent the brittle fracture and splash of the wafer edge during the cleaning and improves the cleaning effect of the wafer edge.

In the cleaning device for a wafer edge according to the embodiments of the present application, a control device is configured to control a rotation speed of a wafer to increase from a first speed to a second speed or decrease from the second speed to the first speed, and the second speed is greater than the first speed. During the cleaning, the rotation speed of the wafer changes between the first speed and the second speed, and a change in the rotation speed of the wafer causes the cleaning solution to produce turbulence on a surface of the wafer. The turbulence may increase an adhesion force between the cleaning solution and the wafer edge, and the cleaning solution reacts more thoroughly with the wafer edge, which facilitates more thorough cleaning of the wafer edge. After the cleaning, the residue is reduced and the cleaning effect of the wafer edge is improved.

Those of ordinary skill in the art may understand that the above implementations are specific embodiments for implementing the present disclosure. However, in practical applications, various changes in forms and details may be made thereto without departing from the spirit and scope of the present disclosure. Any person skilled in the art can make respective changes and modifications without departing from the spirit and scope of the present disclosure. Therefore, the protection scope of the present disclosure should be subject to the scope defined by the claims.

What is claimed is:

1. A cleaning method for a wafer edge, comprising:
providing a wafer, the wafer having a wafer edge; and
controlling the wafer in a rotation phase to rotate the wafer, and providing a cleaning solution for the wafer edge in the rotation phase;
the rotation phase comprising a first rotation phase and/or a second rotation phase, a rotation speed of the wafer increasing from a first speed to a second speed during the first rotation phase, and the rotation speed of the wafer decreasing from the second speed to the first speed during the second rotation phase; and
the second speed being greater than the first speed.

2. The cleaning method for a wafer edge according to claim 1, wherein the rotation speed of the wafer increases linearly from the first speed to the second speed during the first rotation phase; and the rotation speed of the wafer decreases linearly from the second speed to the first speed during the second rotation phase.

3. The cleaning method for a wafer edge according to claim 2, wherein a speed of the linear increase ranges from 200 revolutions per minute per second to 1200 revolutions per minute per second; and a speed of the linear decrease ranges from 200 revolutions per minute per second to 1200 revolutions per minute per second.

4. The cleaning method for a wafer edge according to claim 1, wherein the rotation speed of the wafer increases arithmetically from the first speed to the second speed during the first rotation phase; and the rotation speed of the wafer decreases arithmetically from the second speed to the first speed during the second rotation phase.

5. The cleaning method for a wafer edge according to claim 4, wherein a tolerance of the arithmetic increase ranges from 200 revolutions per minute to 1200 revolutions per minute; and a tolerance of the arithmetic decrease ranges from 200 revolutions per minute to 1200 revolutions per minute.

6. The cleaning method for a wafer edge according to claim 1, wherein the rotation phase comprises the first rotation phase and the second rotation phase alternately performed.

7. The cleaning method for a wafer edge according to claim 1, wherein each first rotation phase and each second rotation phase constitute a cleaning cycle, and the rotation phase comprises a number of cleaning cycles with a same time.

8. The cleaning method for a wafer edge according to claim 7, wherein it takes at least 5 cleaning cycles to clean the wafer.

9. The cleaning method for a wafer edge according to claim 7, wherein a duration of one of the cleaning cycles ranges from 1.2 seconds to 13 seconds.

10. The cleaning method for a wafer edge according to claim 1, wherein the first rotation phase comprises: an acceleration phase and a first stabilization phase; and the second rotation phase comprises: a deceleration phase and a second stabilization phase.

11. The cleaning method for a wafer edge according to claim 10, wherein a duration of the first stabilization phase and a duration of the second stabilization phase range from 0.2 seconds to 0.5 seconds.

12. The cleaning method for a wafer edge according to claim 1, wherein the first speed ranges from 1200 revolutions per minute to 1600 revolutions per minute.

13. The cleaning method for a wafer edge according to claim 12, wherein the second speed ranges from 2000 revolutions per minute to 2400 revolutions per minute.

14. The cleaning method for a wafer edge according to claim 1, prior to said providing a cleaning solution for the wafer edge, further comprising: performing pretreatment, the pretreatment involving providing deionized water for the wafer edge to soften the wafer edge.

15. The cleaning method for a wafer edge according to claim 1, wherein the cleaning solution comprises: a mixed solution of ammonia and hydrogen peroxide, a hydrofluoric acid solution or a nitrofluoric acid solution.

16. A cleaning device for a wafer edge, comprising:
a wafer and a stage configured to place the wafer;
a control device, the control device being configured to control a rotation speed of the wafer, the rotation speed of the wafer increasing from a first speed to a second speed or decreasing from the second speed to the first speed, the second speed being greater than the first speed; and
a spraying device, the spraying device being configured to provide a cleaning solution for the rotating wafer edge.

17. The cleaning device for a wafer edge according to claim 16, wherein an upper surface at the wafer edge is an inclined surface inclined toward a lower surface of the wafer.

18. The cleaning device for a wafer edge according to claim 16, further comprising: a water supply device, the water supply device being configured to provide deionized water for the wafer.

19. The cleaning device for a wafer edge according to claim 16, wherein the control device comprises a timing device, the timing device being configured to record a duration for cleaning the wafer edge.

20. The cleaning device for a wafer edge according to claim 16, wherein the control device is further configured to control a time during which the rotation speed of the wafer increases from the first speed to the second speed to be the same as a time during which the rotation speed of the wafer decreases from the second speed to the first speed.
